(19) United States
(12) Patent Application Publication
(10) Pub. No.: US 2016/0181409 A1
(43) Pub. Date: Jun. 23, 2016

(54) Bidirectional Power Switching with Bipolar Conduction and with Two Control Terminals Gated by Two Merged Transistors

(71) Applicant: Ideal Power Inc., Austin, TX (US)

(72) Inventors: William C. Alexander, Spicewood, TX (US); Richard A. Blanchard, Los Altos, CA (US)

(21) Appl. No.: 14/918,440

(22) Filed: Oct. 20, 2015

Related U.S. Application Data
(60) Provisional application No. 62/065,916, filed on Oct. 20, 2014.
(60) Provisional application No. 62/111,316, filed on Feb. 3, 2015.
(60) Provisional application No. 62/199,193, filed on Jul. 30, 2015.
(60) Provisional application No. 62/236,415, filed on Oct. 2, 2015.

(51) Int. Cl. H01L 29/747; H01L 29/40

(52) U.S. Cl. CPC H01L 29/747; H01L 29/407

(57) ABSTRACT

Power semiconductor devices, methods, and systems, in which additional switches are added on both surfaces of a two-sided power device with bidirectional conduction. The additional switches are preferably vertical trench MOS transistors, and permit the emitter-base junction on either surface to be shunted easily.

### CROSS-REFERENCE

Priority is claimed from U.S. application 62/065,916 (IPC-223P); and from U.S. application 62/111,316 (IPC-238P); and from U.S. application 62/199,193 (IPC-263P); and from U.S. application 62/236,415 (IPC-265P); each of which is hereby incorporated by reference.

### BACKGROUND

The present application relates generally to bidirectional bipolar transistors with two distinct base contact regions at two distinct locations.

Note that the points discussed below may reflect the hindsight gained from the disclosed inventions, and are not necessarily admitted to be prior art.

Published U.S. application US 2014-0375287 disclosed a fully bidirectional bipolar transistor with two base terminals. This structure is generally illustrated in FIG. 3. Both faces of a semiconductor die 310 carry emitter/collector regions 322 which form a junction with the bulk substrate 310. Base contact regions 332 are also present on both faces. This example shows an npn structure, so the emitter/collector regions 322 are n-type, and the base contact regions 332 are p-type. A shallow n+ contact doping 324 provides ohmic contact from separate terminals EC1 and EC2 (on the two opposite faces of the semiconductor die, in this example) to regions 322, and a shallow p+ contact doping 334 provides ohmic contact from separate terminals B1 and B2 (on the two opposite faces of the die) to regions 332. In this example, dielectric-filled trenches 340 provide lateral separation between base contact regions 332 and emitter/collector regions 322. (Note that a p-type diffused region may be added to reduce the series resistance between the emitter-to-base junction and the base contact.)

A somewhat similar structure was shown and described in application WO2014/122472 of Wood.

Application US 2014-0375287 also describes some surprising aspects of operation of the device. Notably: 1) when the device is turned on, it is preferably first operated merely as a diode, and base drive is then applied to reduce the on-state voltage drop. 2) Base drive is preferably applied to the base nearest whichever emitter/collector region will be acting as the collector (as determined by the external voltage seen at the device terminals). 3) A two-stage turnoff sequence is preferably used. 4) In the off state, base-emitter voltage (on each side) is limited by an external low-voltage diode which parallels that base-emitter junction.

The present application teaches a new kind of bidirectional power switching device with bipolar conduction. These novel devices include emitter/collector regions and base contact regions in two distinctly separate locations (e.g. opposite faces of a semiconductor die), and also (on both faces) a trench electrode which has a dual function. 1) The trench electrode operates as a field plate in the off state, to spread out the lines of isopotential (and hence reduce peak electric field for a given voltage, and hence increase the breakdown voltage). 2) The trench electrode also acts as the gate of a vertical field-effect transistor which shunts the junction between the emittor/collector region and the bulk of the semiconductor wafer.

This structure works synergistically with the staged turn-ON of bipolar conduction. By turning ON the transistor to shunt the reverse-biased junction at the collector side of the device, diode-mode conduction is initiated without any base current being applied. (The externally applied voltages will determine which of the emitter/collector regions is momentarily the collector, and which is the emitter. For example, in an npn structure, where the emitter/collector regions are both n-type, whichever emitter/collector is connected to the more positive external voltage will be the “collector” side.)

This structure also works synergistically with staged turn-OFF of bipolar conduction. By leaving the merged transistor ON while base current is interrupted or temporarily reversed, a “pre-turnoff” stage of operation is performed to reduce the carrier population.

This structure has even more synergistic advantages when used with both pre-turnoff and diode-mode turn-on.

### BRIEF DESCRIPTION OF THE DRAWINGS

The disclosed inventions will be described with reference to the accompanying drawings, which show important sample embodiments and which are incorporated in the present specification by reference, wherein:

FIG. 1A schematically shows a first example of a six-terminal device as described below.

FIG. 1B is a three-dimensional representation of a different example of the six-terminal device described below.

FIG. 2 shows a circuit symbol for the device of FIG. 1A or 1B.

FIG. 3 schematically shows a four-terminal bidirectional two-base bipolar device as described above, and FIG. 4 shows a circuit symbol for the device of FIG. 3.

FIG. 5 shows a modified version of the device of FIG. 1.

FIGS. 6A-6D show an example of a fabrication sequence which can be used to build the device of FIG. 5.

FIG. 7 shows a doping profile, along the surface of the gate, which is used in the device of FIG. 1A; and

FIG. 8 shows a doping profile, along the surface of the gate, which is used in the device of FIG. 5. In each case, the dotted line shows the contribution of the low-resistance base region.

FIG. 9 is a perspective view of a further modification of the device of FIG. 5.

FIG. 10 shows another contemplated modification of the device of FIG. 5.

FIG. 11 shows another contemplated modification of the device of FIG. 5. In this case a vertical trench transistor is located amidst the emitter/collector region.

FIG. 12 shows another contemplated modification of the device of FIG. 5. In this case vertical trench transistors are located both amidst and also at the edges of the emitter/collector region.

FIG. 13 shows a technique for forming a p-type source.

FIG. 14 shows another technique for forming a p-type source.

FIG. 15 shows yet another technique for forming a p-type source.

FIG. 16 shows an angle-implant technique.

FIG. 17 shows another angle-implant technique.

FIG. 18 shows an example of a control circuit which can be used for an innovative device like that of FIG. 1A.

### DETAILED DESCRIPTION OF SAMPLE EMBODIMENTS

The numerous innovative teachings of the present application will be described with particular reference to presently preferred embodiments (by way of example, and not of limitation). The present application describes several inventions, and none of the statements below should be taken as limiting the claims generally.

### Previously Patented “B-TRAN” Structures

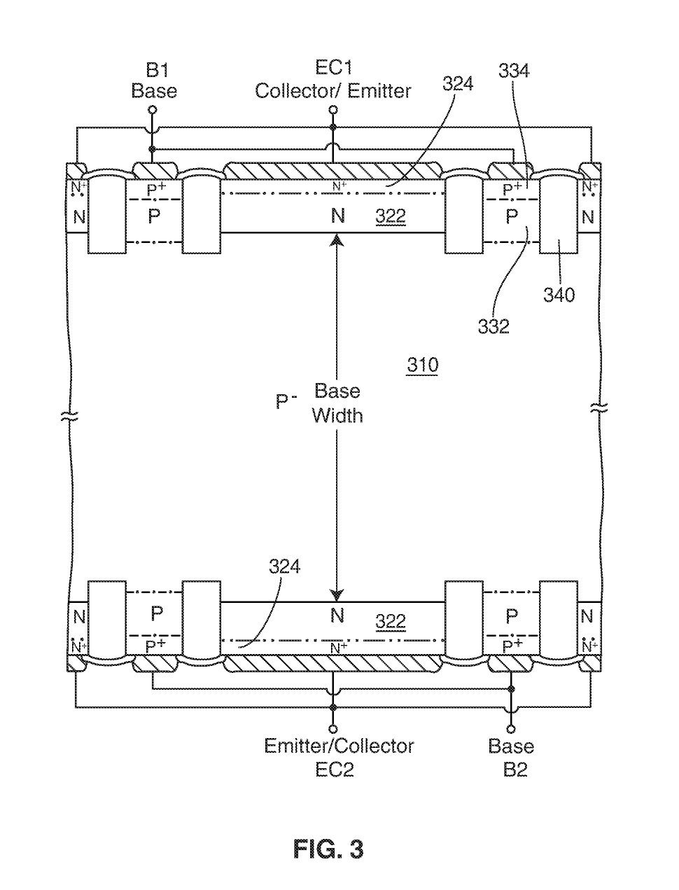

The present application discloses a new kind of bi-directional bipolar transistor. For comparison, we first discuss the “B-TRAN” devices shown in US 2014-0375287; these are typically three layer, four terminal devices, as shown in FIG. 3. This device is a symmetrical device, meaning that the polarity of the voltage on the two “end” terminals EC1/EC2 determines which of these two terminals functions as the emitter (i.e. has a forward biased junction), and which of these terminals functions as the collector (i.e. has a reverse biased junction). Such a B-TRAN typically has a current gain (beta) in the range of 5-20, and when biased “off,” is capable of withstanding a high voltage in either direction. In addition, as a bipolar transistor, it has a minimum on-voltage (Vice-sat) that can be as low as 0.2 volts, which is well below the voltage drop of a junction diode in silicon (0.6 volts). Since the B-TRAN is symmetrical, it can be used in any circuit requiring a bi-directional switch. A device symbol that shows the symmetry of a B-TRAN is shown in FIG. 4. Note that this is a four-terminal device: external terminals include two separate emitter/collector terminals EC1 and EC2, and two separate base terminals B1 and B2.

The current gain of a B-TRAN is the ratio of the collector current to the base current. As mentioned above, this value, for a four terminal B-TRAN, is typically in the range of 5-20. The lower gain occurs in a B-TRAN with a high voltage rating, such as 1200V, while the higher gain occurs in a B-TRAN with a lower voltage rating, such as 600V. This current gain means that the base current for a 200 A device would be in the range of 10 A-40 A. This is a substantial amount of current. The current gain is also a function of the current density, decreasing as the current density increases.

### First Example

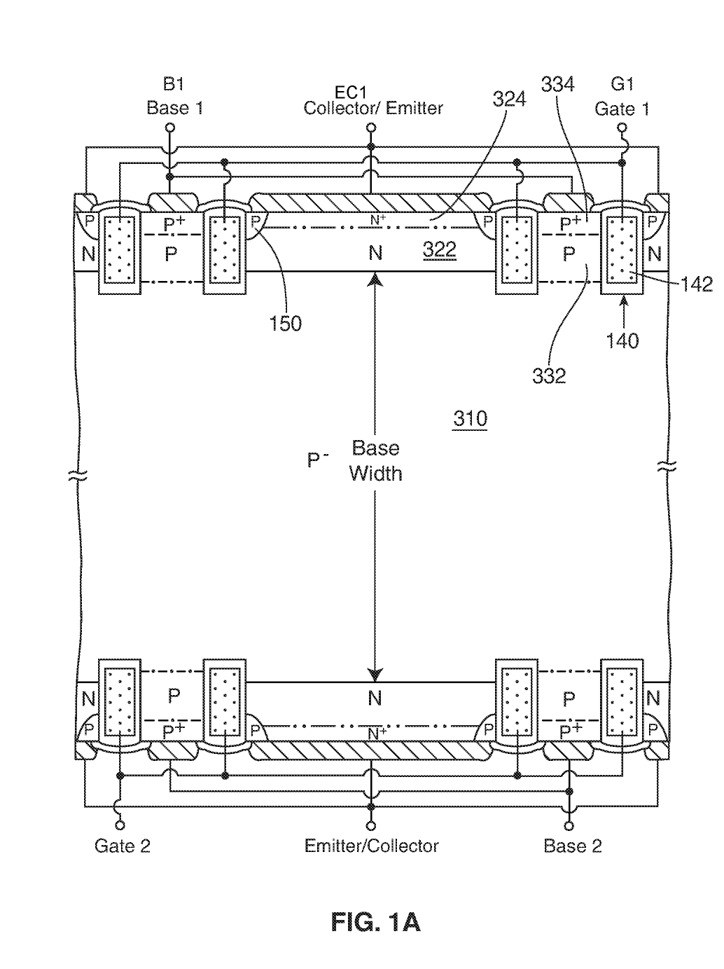

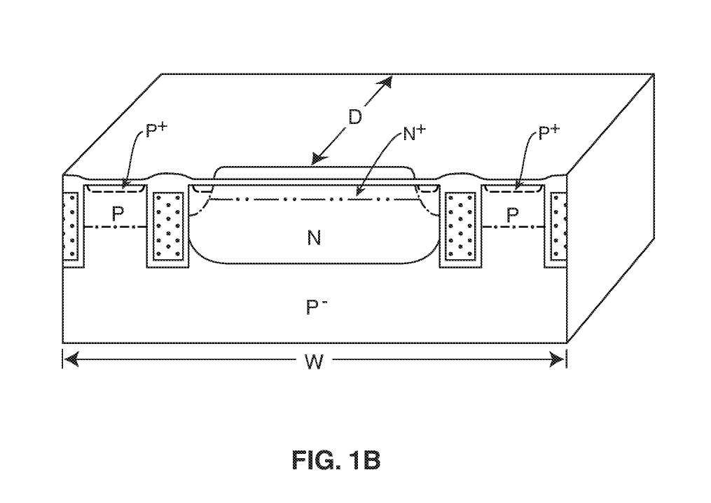

The present application shows how to retain the advantages of the B-TRAN device while also decreasing the drive current required in some operating modes. A structure that accomplishes this goal is shown in FIG. 1A. This figure, while having some parts similar to those of FIG. 3, has several significant changes, as follows.

First, note that the trenches 340 previously used to separate the emitter/collector regions 322 from the base regions 332 have been replaced by trenches 140. These trenches 140 include an insulated conductive electrode 142, made e.g. of doped poly silicon, so that each trench 140 contains a gate 142 that can be used to apply a voltage to the silicon adjacent to the gate. (The spacing between the MOSFETs can be adjusted to obtain the desired amount of current that is supplied by the MOSFETs.)

Second, note that P+ dopant has been introduced into the silicon adjacent to the top of the trench, forming the P+ source regions 150 of a P-channel trench DMOS transistor. (It may be necessary to avoid introducing N+ dopant at the trench sidewall, in order to allow the P+ dopant to have a sufficiently high concentration to form these P+ sources.) This P-channel “TrenchFET” can supply current directly to the base region of the bipolar NPN transistor when the gate is properly biased.

FIG. 18 shows an example of a control circuit which can be used for an innovative device like that of FIG. 1A.

### Fabrication Steps

Fabrication of the basic B-TRAN structure is straight-forward. Fabrication of the M-TRAN of FIG. 1A is only slightly more complicated. The main challenge, in modifying the B-TRAN process, is to optimize the channel length and doping of the vertical FET. That need in turn requires controlled formation of the p-type region which is the source of the vertical transistor. One preferred example of fabrication will now be described.

In this example, all dopant introductions (after the original bulk doping of the die) are performed by ion implantation. However, other doping techniques can be used.

Process parameters are given for a 600V process, but of course the examples given are merely illustrative, and can be adjusted for scaling or for characteristics of different processes. In this example, the physical thickness of the finished device is about 70 microns, but the initial thickness of the wafer will be 600-700 microns. The bulk resistivity is approximately 80-150 ohm-cm. The process sequence forms all of the regions on one side of the wafer (the “front”), bonds a handle wafer to that side, thins and polishes the wafer to its final thickness, and then forms all of the regions on the other side (the “back” side). The maximum depth of the emitter/collector region(s) is e.g. 4-6 microns.

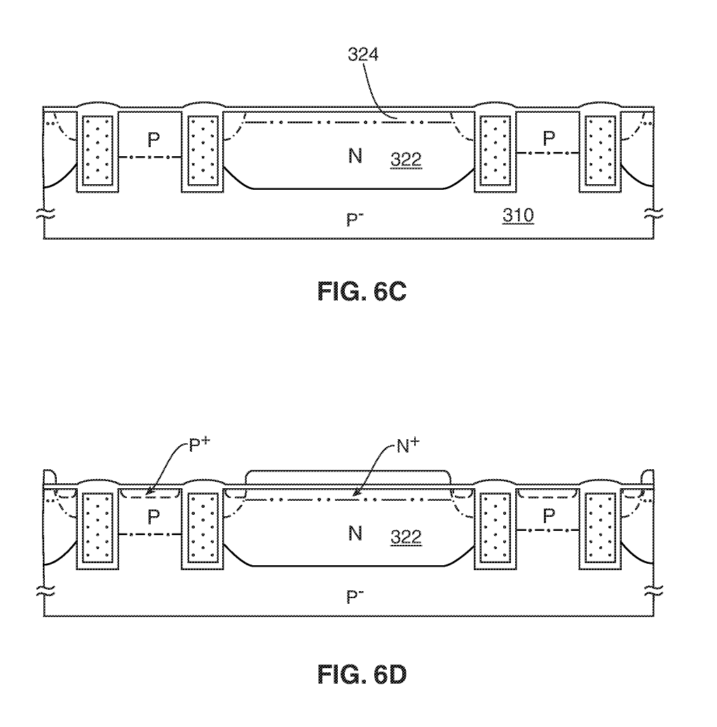

FIG. 6A shows a first implantation stage in fabrication. Prior to this step, the trenches 140, and the electrodes 142 within them have already been formed. The trenches are preferably etched anisotropically to form approximately vertical sidewalls, and a gate oxide of approximately 50-200 nm thick is grown on the sidewalls. A bottom oxide can be the same thickness, or can be e.g. 200-500 nm thick, avoiding low breakdown if the sidewall oxide is thin. The gate electrode is preferably doped polysilicon, but alternatively can be polycide or another conductor.

When thick bottom oxide is desired, one presently-preferred exemplary formation technique is to deposit nitride over a thin layer of thermal oxide on the trench sidewalls and bottom, then etch away the nitride on the trench bottom and perform another thermal oxidation. The oxide only grows on the bottom where the nitride has been removed.

Phosphorus is now implanted, e.g. with a dose of 10¹⁴ to 5×10¹⁵ cm⁻² at 20-200 keV. Note that this implantation is done into less than all of the emitter/collector region: instead, the trenches are shielded by patterned masking layer 612, so that the exposed area 610 is offset from the trenches 140 by 4-8 microns. This offset provides important advantages, as will be seen below.

Phosphorus is a fast diffuser. The phosphorus ions implanted in this step will form the deep portion 322 of the emitter/collector of the vertical NPN bipolar transistor, as well as the body region of the p-channel trench MOSFET.

Next, Arsenic (As) is implanted into the same opening, with a dose of e.g. 5×10¹⁴ to 10¹⁶ cm⁻². Arsenic is a slow diffuser, so the implanted arsenic ions remain relatively close to the surface of the substrate, providing a low resistance, ohmic contact 324 to the deeper n-type region 322, as shown in FIG. 1A. This step completes the steps of FIG. 6A.

Next, a complementary masking layer 622 is put in place, leaving area 620 open. Masking layer 622 is preferably complementary to the masking layer 612, but may have some slight overlap or underlap. Similarly, open area 620 is preferably complementary to open area 610, but may have some slight overlap or underlap. Masking layer 622 can be formed from patterned masking layer 612 by any of the various known color-reversal processes, or can be directly patterned.

Boron is now implanted into open areas 620, e.g. with a dose of 10¹³ to 10¹⁵ cm⁻² at an energy of 10-200 keV.

Boron is a fast diffuser. The implanted boron will form the p-type layer 332, reducing the resistance of the base between the base contact and the base-to-emitter junction, and thereby improving the NPN bipolar transistor performance. This completes the steps shown in FIG. 6B.

A thermal step is now performed to drive in the boron, and the masking layer 622 is removed. This results in the structure shown in FIG. 6C.

After metallization steps, a low energy implant is now performed. This can be, for example, 5×10¹⁴-5×10¹⁵/cm⁻² of BF₂ at 10-50 keV. This implant is preferably annealed using a low temperature. The presence of aluminum metallization on one side of the wafer when the other side receives this implantation restricts the maximum temperature for an implant anneal step to approximately 450 C or less, resulting in only partial activation of the implanted boron ions. However, even this partial activation reduces the contact resistance to the p-type regions.

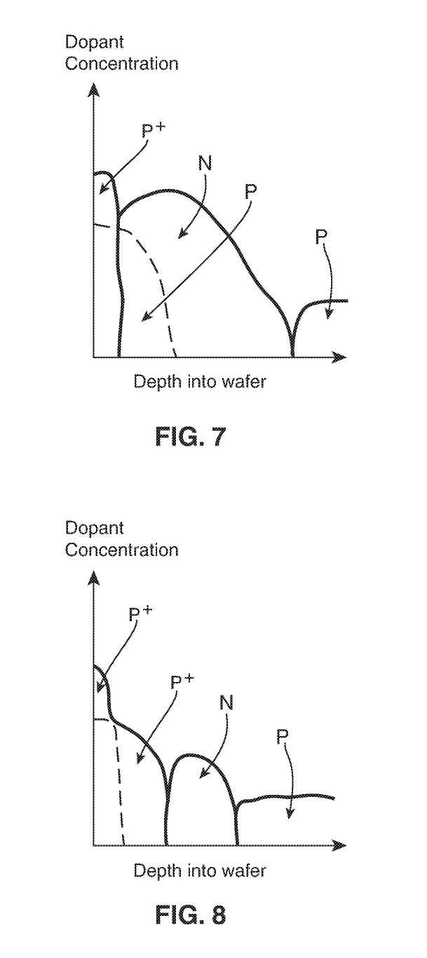

In the normal flow for a two-sided or “bi-directional” device, the drive-in step is performed after implant steps 1, 2, and 3 have been completed on both sides of the wafer. Then follow the remainder of the processing steps, includes P+ contact formation followed by contact mask and etch, metal deposition step followed by metal mask and etch, and passivation deposition followed by passivation mask and etch. After these steps, the M-TRAN structure shown in FIG. 6 has been formed. While this structure looks as though it will perform as an M-TRAN, the use of phosphorus and boron as the doping species makes it difficult to obtain a short channel length in the p-channel MOSFET. This difficulty results from the need to simultaneously diffuse these two species that have been implanted on both sides of the wafer to their final junction depth and dopant profile. Since the p-type diffused region is typically shallower that the n-type emitter region, a lower dose boron implant is used. Though this boron is present adjacent to the side of the gate, the higher concentration of phosphorus in this region compensates for the boron. Therefore, even though no arsenic is implanted in the silicon adjacent to the gate trench, only the P+ implant at the wafer surface has a sufficiently high concentration to provide a P+ region, as is shown in the doping profiles of FIGS. 7 and 8.

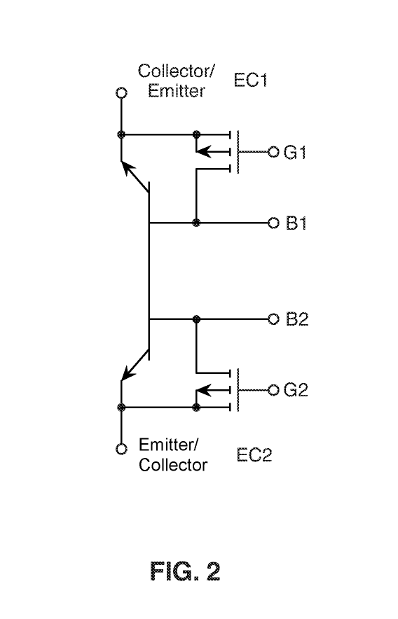

The present application solves the problem of the implanted phosphorus compensating the boron implant, which in turn results in a long channel (and hence high resistance) p-channel MOSFET by introducing both the phosphorus and the arsenic only in regions that are a specified distance away from the gate dielectric as shown in FIG. 2. When this distance is properly chosen, the phosphorus diffuses both laterally and vertically producing the structure shown in FIG. 1A. The arsenic region is inside the phosphorus region, also an adequate distance from the gate region. The resulting doping profile is shown in FIG. 8, which has a channel region that is both shorter and has a lower peak dopant concentration, thereby resulting in a lower device on-resistance.

The threshold voltage of each region of the p-channel MOSFET is, in part, set by the peak value of the n-type dopant concentration in the body region. This value will be different on the left and right sides of the emitter region unless the phosphorus diffusion is exactly centered between the trench gates. However, the difference in the threshold voltage of these two sides will not significantly affect device performance as long as the gate voltage fully turns on both sides of the MOSFET. Any difference in channel length should also be minor and not affect overall device performance. Threshold voltage is typically in the range of e.g. 2-7 V, but can also be e.g. as high as 10 V.

The source and gate that are part of the p-channel MOSFET can be incorporated in B-TRAN devices having a variety of geometries to produce the M-TRAN, including B-TRANs having both interdigitated and cellular structures. In addition, the presence of these device regions should not affect M-TRAN breakdown voltage as long the geometry and the processing details are selected appropriately.

In some sample embodiments, arsenic or phosphorus can also be implanted in the N+ contact regions to further reduce the contact resistance to both n-type single crystal and poly silicon.

### Alternatives for Source Formation

Alternate techniques also exist, for forming the p-type source region of the p-channel MOSFET along the sidewall of the trench in an M-TRAN, that are compatible with the B-TRAN process flow.

Three different techniques are shown below for forming a deep, heavily doped p-type region that can serve as the source of a p-channel MOSFET along the sidewall of the trench that separates the n-type emitter region form the p-type base contact region. These three techniques are shown in the three figures below.

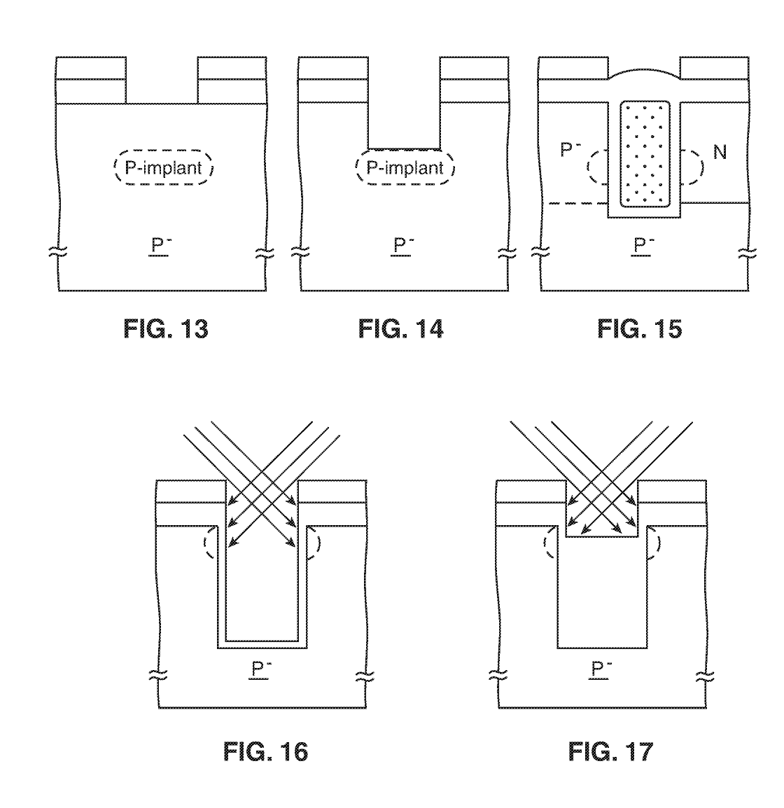

As shown in FIG. 13, one technique is to use a high energy implant step to introduce p-type dopant at a desired depth into the wafer. The energy and dose will determine the final dopant profile. Multiple implants at different energies may be used to allow the implanted distribution to contact the P+ dopant at the wafer surface. Care must be taken to use a masking layer that prevents the unwanted implantation of the species in other areas of the wafer.

Another technique is to use an implantation step after the trench has been etched to a fraction of its final depth, as shown in FIG. 14, and then etch the remainder of the trench. This technique may also be used multiple times to provide a dopant distribution that is contacted by the P+ region on the surface of the wafer.

Yet another alternative is to perform a high energy implantation after the trench has been etched and filled, as shown in FIG. 15. Multiple implants may be performed so that the p-type region contacts the P+ region at the surface of the wafer.

### Six-Terminal Operation

The structure of FIG. 1A has both a gate terminal and a base terminal on each surface. These four control terminals can be used in combination to turn the M-TRAN “ON” and “OFF” in the most efficient manner for a given circuit. For instance, the gate terminal can be used to turn the device at one surface from “OFF” to “ON,” without requiring current to be supplied by the base terminal on the same surface. However, to turn this device from “ON” to “OFF,” applying a voltage to the base terminal, thereby actively removing carriers from regions of the M-TRAN, may result in the most efficient turn-off behavior. In addition, combinations of voltages may be applied to each of the four terminals during turn-ON, turn-OFF, or at any other time.

The inclusion of the MOSFET on the chip with the bipolar transistor also decreases the effect of external components, resulting in better performance.

The gate electrode also acts as a field plate improving the breakdown voltage, since the voltage on the gate is within a few volts of the voltage on the adjacent emitter/collector. One possible circuit symbol for the M-TRAN of FIG. 1A is shown in FIG. 2.

The structure of FIG. 1A has a performance per unit area is not as good as that of an equivalent B-TRAN device. The present application also describes further enhancements to the M-TRAN device of FIG. 1A, which improve its performance, and which also allow its performance to be tailored to different applications. Three possible improvements are discussed below.

### Further Example

### Increased Area Fraction for Emitter/Collector

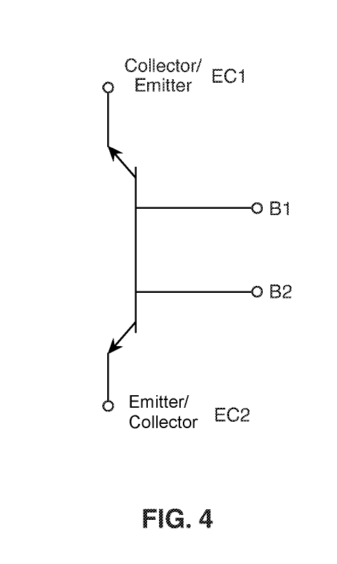

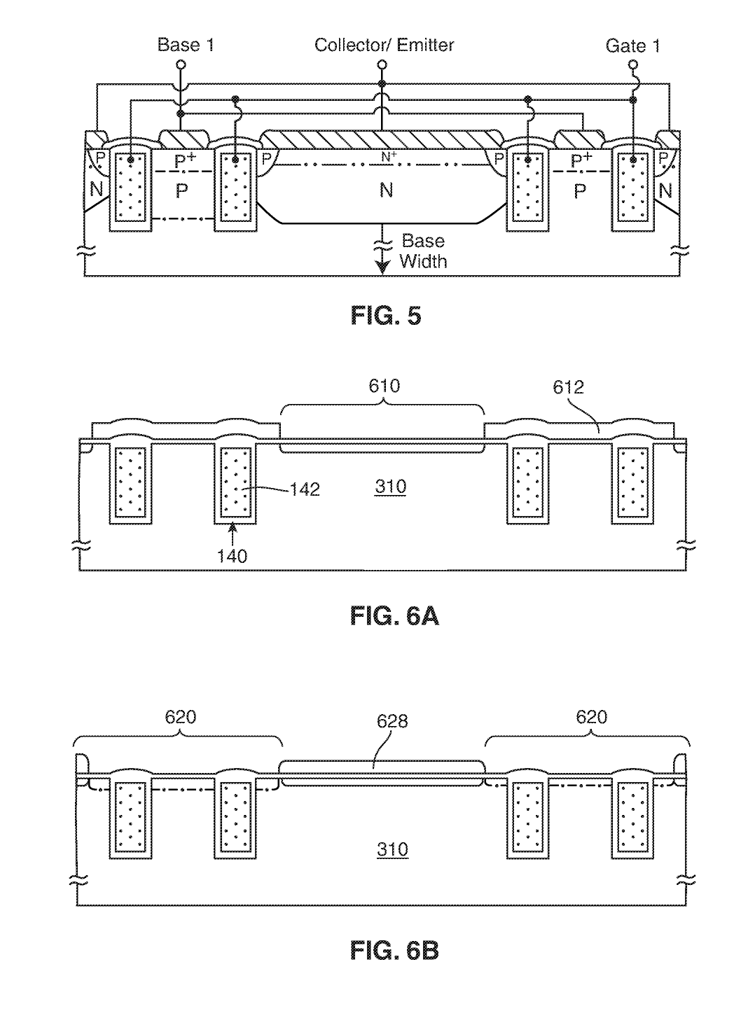

A further alternative is to increase the relative percentage of the surface area that functions as the bipolar transistor emitter. In the simplest implementation of the M-TRAN structures of FIGS. 1A, 1B, and 5, the amount of injecting MOS source edge in a cell is “2D,” where “D” is the depth of the cell as shown in FIG. 1B. The ratio of injecting MOS source edge to cell area given a cell width “W” is 2D/W*D or 2/W.

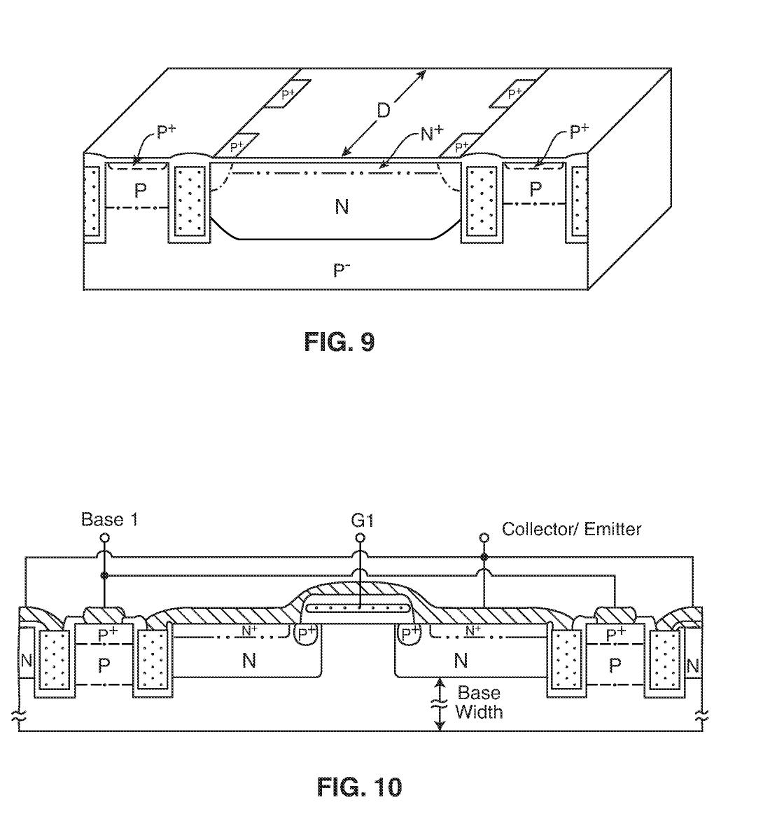

However, it is also contemplated that the performance of the M-TRAN might be improved if the entire region adjacent to the isolation trench at the edges of the emitter was not injecting MOS source edge. Such a configuration can be obtained by forming MOS sources along only part of the isolation trench as shown in FIG. 9. In this geometry, the amount of MOS source edge can be adjusted independently of the amount of emitter perimeter, as long as the amount of MOS source edge is less that the amount of emitter perimeter.

### Further Example

### Gate Portions Remote from Base Contact

In a further class of alternatives, some or all of the DMOS transistor is formed at a location that is not adjacent to the isolation trench. The location of the MOS source adjacent to the trench that separates the base contact region from the emitter/collector region results in a convenient device layout, but there are other options for the location of the MOS transistor.

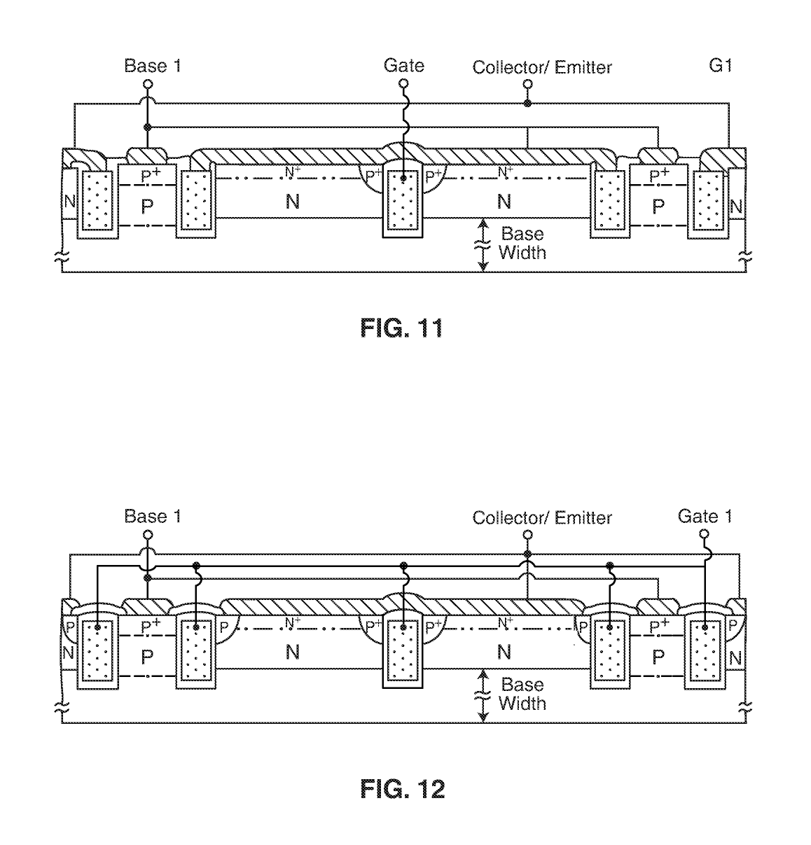

For example, if it is determined that location the field-effect transistor adjacent to the isolation trench has any disadvantages, a MOS transistor can be placed in the center of the cell as shown in FIG. 10. In this figure, the MOS transistor is a planar DMOS transistor. Planar DMOS transistors may not be as efficient as trench DMOS transistors, so alternatively trench DMOS structure may also be used as shown in FIG. 11.

In the structures of FIGS. 10 and 11, the isolation trench serves as a buried field plate, not as the gate of a trench DMOS transistor. However, it is also possible to utilize both a trench at the center of the emitter while also using the isolation trenches as MOS transistor gates, thereby increasing the amount of MOS source edge, and obtaining lower MOS transistor on-resistance as shown in FIG. 12.

### Further Example

### P-Type Poly Gate

In yet another alternative, it is contemplated that the polysilicon layer which forms the gate electrode can be doped p-type (e.g. doped with boron). For a p-channel MOSFET, doping the gate poly with boron instead of arsenic or phosphorus results in a threshold voltage or “Vth” that has an absolute value in the range of 1 volt lower that when the gate is doped with arsenic or phosphorus. For applications with a limited gate drive voltage, this reduction in threshold voltage can be quite important. Doping the gate poly with boron is performed by allowing boron into the gate poly, while using a masking layer to prevent the introduction of either arsenic or phosphorus during the normal process flow.

Advantages

The disclosed innovations, in various embodiments, provide one or more of at least the following advantages. However, not all of these advantages result from every one of the innovations disclosed, and this list of advantages does not limit the various claimed inventions.

Improved efficiency in power conversion systems;

Low ON-state voltage drop;

Fast switching;

Improved control.

According to some but not necessarily all embodiments, there is provided: Power semiconductor devices, methods, and systems, in which additional switches are added on both surfaces of a two-sided power device with bidirectional conduction. The additional switches are preferably vertical trench MOS transistors, and permit the emitter-base junction on either surface to be shunted easily.

According to some but not necessarily all embodiments, there is provided: A semiconductor device, comprising: first and second emitter/collector regions, located respectively on first and second faces of a die of semiconductor material, and each doped to have a first conductivity type; wherein the die has a second conductivity type in the bulk thereof; first and second base contact regions, located respectively on the first and second faces of the die, and each doped to have the second conductivity type; first and second insulated gate electrodes which each lie in a trench, and are vertically extended alongside the first and second emitter/collector regions respectively; first and second source regions, located at the edge of the respective emitter/collector regions alongside the trench, and separated from the bulk of the wafer by the emitter/collector region; wherein the gate electrodes are capacitively coupled to selectably invert portions of the emitter/collector regions which are adjacent to a respective gate electrode; whereby the gate electrodes can turn on conduction, even if no current is passed through either base contact region, by selectably inverting the adjacent portions of the respective emitter/collector region; and whereby the gate electrode also improves the breakdown voltage between the two emitter/collector regions.

According to some but not necessarily all embodiments, there is provided: A semiconductor device, comprising: first and second emitter/collector regions, located respectively on first and second faces of a wafer of semiconductor material, and each doped to have a first conductivity type; wherein the wafer has a second conductivity type in the bulk thereof; first and second base contact regions, located respectively on the first and second faces of the wafer, and each doped to have the second conductivity type; first and second insulated gate electrodes which each lie in a trench, and are vertically extended alongside the first and second emitter/collector regions respectively; wherein the trench laterally surrounds the emitter/collector regions, and laterally separates the emitter/collector regions from the base contact regions; first and second source regions, connected to and located in the respective emitter/collector regions at an edge alongside the trench, and separated from the bulk of the wafer by the emitter/collector region; wherein the gate electrodes are capacitively coupled to selectably invert adjacent portions of the emitter/collector regions; and wherein the trenches are deeper than the adjacent portions of the respective emitter/collector regions; whereby one of the gate electrodes can turn on conduction, even if no current is passed through either base contact region, by inverting the adjacent portion of the respective emitter/collector region; and whereby the gate electrodes also improve the breakdown voltage between the two emitter/collector regions.

According to some but not necessarily all embodiments, there is provided: A semiconductor device, comprising: first and second n-type emitter/collector regions, located respectively on first and second faces of a die of p-type semiconductor material; first and second p-type base contact regions, located respectively on the first and second faces of the die; first and second insulated gate electrodes which each lie in a trench, and are vertically extended alongside the first and second emitter/collector regions respectively; wherein the gate electrodes are made of polycrystalline p-type semiconductor material; first and second p-type source regions, connected to and located in the respective emitter/collector regions at an edge alongside the trench, and separated from the bulk of the wafer by the emitter/collector region; wherein the gate electrodes are capacitively coupled to selectably invert adjacent portions of the emitter/collector regions; whereby one of the gate electrodes can turn on conduction, even if no current is passed through either base contact region, by inverting the adjacent portion of the respective emitter/collector region; and whereby the gate electrodes also improve the breakdown voltage between the two emitter/collector regions.

According to some but not necessarily all embodiments, there is provided: A system, comprising: first and second AC power connections; and a bipolar bidirectional transistor interposed between the power input connection, comprising: first and second emitter/collector regions, located respectively on first and second faces of a die of semiconductor material, and each doped to have a first conductivity type; wherein the die has a second conductivity type in the bulk thereof; first and second base contact regions, located respectively on the first and second faces of the die, and each doped to have the second conductivity type; first and second insulated gate electrodes which each lie in a trench, and are vertically extended alongside the first and second emitter/collector regions respectively; first and second source regions, located at the edge of the respective emitter/collector regions alongside the trench, and separated from the bulk of the wafer by the emitter/collector region; wherein the gate electrodes are capacitively coupled to selectably invert portions of the emitter/collector regions which are adjacent to a respective gate electrode; whereby the gate electrodes can turn on conduction, even if no current is passed through either base contact region, by selectably inverting the adjacent portions of the respective emitter/collector region; and whereby the gate electrode also improves the breakdown voltage between the two emitter/collector regions.

According to some but not necessarily all embodiments, there is provided: A system, comprising: first and second AC power connections; and a bipolar bidirectional transistor interposed between the power input connection, comprising: first and second emitter/collector regions, located respectively on first and second faces of a wafer of semiconductor material, and each doped to have a first conductivity type; wherein the wafer has a second conductivity type in the bulk thereof; first and second base contact regions, located respectively on the first and second faces of the wafer, and each doped to have the second conductivity type; first and second insulated gate electrodes which each lie in a trench, and are vertically extended alongside the first and second emitter/collector regions respectively; wherein the trench laterally surrounds the emitter/collector regions, and laterally separates the emitter/collector regions from the base contact regions; first and second source regions, connected to and located in the respective emitter/collector regions at an edge alongside the trench, and separated from the bulk of the wafer by the emitter/collector region; wherein the gate electrodes are capacitively coupled to selectably invert adjacent portions of the emitter/collector regions; and wherein the trenches are deeper than the adjacent portions of the respective emitter/collector regions; whereby one of the gate electrodes can turn on conduction, even if no current is passed through either base contact region, by inverting the adjacent portion of the respective emitter/collector region; and whereby the gate electrodes also improve the breakdown voltage between the two emitter/collector regions.

According to some but not necessarily all embodiments, there is provided: A system, comprising: first and second AC power connections; and a bipolar bidirectional transistor interposed between the power input connection, comprising: first and second n-type emitter/collector regions, located respectively on first and second faces of a die of p-type semiconductor material; first and second p-type base contact regions, located respectively on the first and second faces of the die; first and second insulated gate electrodes which each lie in a trench, and are vertically extended alongside the first and second emitter/collector regions respectively; wherein the gate electrodes are made of polycrystalline p-type semiconductor material; first and second p-type source regions, connected to and located in the respective emitter/collector regions at an edge alongside the trench, and separated from the bulk of the wafer by the emitter/collector region; wherein the gate electrodes are capacitively coupled to selectably invert adjacent portions of the emitter/collector regions; whereby one of the gate electrodes can turn on conduction, even if no current is passed through either base contact region, by inverting the adjacent portion of the respective emitter/collector region; and whereby the gate electrodes also improve the breakdown voltage between the two emitter/collector regions.

According to some but not necessarily all embodiments, there is provided: A method of operating a bidirectional vertically symmetric bipolar transistor which includes, in two separate locations, a respective trench MOS transistor shunting a respective emitter/base junction as well as a respective base contact terminal, comprising the actions of: a) at turn on, driving a gate terminal of one of the trench MOS transistors, to thereby initiate conduction without turning on bipolar transistor operation; and thereafter b) driving base current through one of the base contact terminals, to thereby initiate bipolar transistor operation; and thereafter c) ceasing step b) when bipolar transistor operation is no longer desired.

According to some but not necessarily all embodiments, there is provided: A method of operating a bidirectional vertically symmetric bipolar transistor which includes, on both front and back surfaces of a semiconductor die, a first-conductivity type emitter/collector region which forms an emitter/base junction to the second-conductivity-type bulk of the semiconductor die, and also a respective MOS trench transistor which shunts the emitter/base junction, and also a respective base contact terminal which provides an ohmic path to the bulk of the semiconductive layer, comprising the actions of: a) at turn on, driving a gate terminal of one of the trench MOS transistors, to thereby initiate conduction as a diode, without turning on bipolar transistor operation; and thereafter b) driving base current through one of the base contact terminals, to thereby initiate bipolar transistor operation and lower the voltage drop between the emitter/collector regions on the two sides; and thereafter c) separately ceasing steps a) and b), at different times.

According to some but not necessarily all embodiments, there is provided: A method of fabricating a bidirectional vertically symmetric bipolar transistor which includes, in two separate locations, a respective trench MOS transistor shunting a respective emitter/base junction as well as a respective base contact terminal, comprising the actions of, in no particular order except as specified: a) forming, in the two separate locations, first and second insulated gate electrodes which each lie in a trench, and are vertically extended; b) introducing, in the two separate locations, first conductivity type dopants into exposed emitter/collector areas which are laterally spaced from the trench; wherein the wafer has a second conductivity type in the bulk thereof; c) introducing, in the two separate locations, second conductivity type dopants into source region locations which are outside the exposed emitter/collector areas and are adjacent to the trench, and also into base contact locations which are separated from the exposed emitter/collector areas by the trench; and d) driving and activating the dopants, so that the emitter/collector regions form a bottom junction which is shallower at locations adjacent the trenches than at other locations; wherein, after steps a) through d), the gate electrodes are capacitively coupled to first-conductivity-type portions of the emitter/collector regions which are more lightly doped than other portions of the emitter/collector regions; whereby the gate electrodes control vertical conduction at adjacent edges of the respective emitter/collector regions.

According to some but not necessarily all embodiments, there is provided: A method of fabricating a bidirectional vertically symmetric bipolar transistor which includes, on both faces of a semiconductor wafer, a respective trench MOS transistor shunting a respective emitter/base junction as well as a respective base contact terminal, comprising the actions of, in no particular order except as specified: a) forming, on both faces of the wafer, first and second insulated gate electrodes which each lie in a trench, and are vertically extended; b) introducing, on both faces of the wafer, first conductivity type dopants into exposed emitter/collector areas which are laterally spaced from the trench; wherein the wafer has a second conductivity type in the bulk thereof; c) introducing, on both faces of the wafer, second conductivity type dopants into source region locations which are outside the exposed emitter/collector areas and are adjacent to the trench; and d) diffusing and activating the dopants, so that the emitter/collector regions form a bottom junction which is shallower at locations adjacent the trenches than at other locations; wherein, after steps a) through d), the gate electrodes are capacitively coupled to first-conductivity-type portions of the emitter/collector regions which are more lightly doped than other portions of the emitter/collector regions; whereby the gate electrodes control vertical conduction at adjacent edges of the respective emitter/collector regions.

According to some but not necessarily all embodiments, there is provided: A method of fabricating a bidirectional vertically symmetric bipolar transistor, comprising the actions of, in no particular order except as specified: on a front surface of a semiconductor wafer, a) forming an insulated gate electrode which lies in a trench, and is vertically extended; b) introducing first conductivity type dopants into exposed emitter/collector areas which are laterally spaced from the trench; c) introducing second conductivity type dopants into source region locations which are outside of and adjacent to the exposed emitter/collector areas, and also into base contact locations which are separated from the exposed emitter/collector areas by the trench; and d) driving and activating the dopants, so that dopants from the exposed emitter/collector areas form emitter/collector regions having a bottom junction which is shallower at locations adjacent the trenches than at other locations; and repeating actions a) through d) on a back surface of the semiconductor wafer; wherein the wafer has a second conductivity type in the bulk thereof; wherein, after actions a) through d), the gate electrodes are capacitively coupled to first-conductivity-type portions of the emitter/collector regions which are more lightly doped than other portions of the emitter/collector regions; whereby the emitter/collector regions, together with the bulk of the wafer, define a bipolar junction transistor; and whereby the gate electrode defines a field effect transistor which bypasses one of the two junctions of the bipolar junction transistor.

Modifications and Variations

As will be recognized by those skilled in the art, the innovative concepts described in the present application can be modified and varied over a tremendous range of applications, and accordingly the scope of patented subject matter is not limited by any of the specific exemplary teachings given. It is intended to embrace all such alternatives, modifications and variations that fall within the spirit and broad scope of the appended claims.

The transistor which includes the gate electrode, and the nearby portion of the emitter/collector, is a “MOS” transistor. The acronym “MOS” originally stood for Metal-Oxide-Semiconductor, but this term nowadays simply refers to a structure where a conductive layer is capacitively coupled through an insulating layer, to a semiconductor material. The insulating layer is not necessarily oxide, but can be any dielectric; the conducting electrode does not have to be a metal, but can be e.g. doped polysilicon.

For one example, the semiconductor material does not have to be silicon, but can be Si:Ge, or SiC, or other IV:IV alloys. Alternatively, it is contemplated that other compound semiconductor materials can be used.

The structures described in the preferred embodiments above are at least three-layer six-terminal devices. However, it is also possible to integrate multiple power devices on a die, or even power devices plus analog devices, especially if full dielectric isolation is used.

In the examples discussed above, arsenic, boron, and phosphorus were chosen as the dopant atoms. Other dopant atoms can also be used with no compromise in device performance. For instance, antimony, which is a slow diffusing n-type dopant atom, can be substituted for arsenic. In a similar fashion, indium, which is a slow diffusing p-type dopant atom, can be used to dope the P+ contact region and be introduced into the appropriate regions before the simultaneous drive-in step that is used to form the P+ contact region.

None of the description in the present application should be read as implying that any particular element, step, or function is an essential element which must be included in the claim scope: THE SCOPE OF PATENTED SUBJECT MATTER IS DEFINED ONLY BY THE ALLOWED CLAIMS. Moreover, none of these claims are intended to invoke paragraph six of 35 USC section 112 unless the exact words “means for” are followed by a participle.

The claims as filed are intended to be as comprehensive as possible, and NO subject matter is intentionally relinquished, dedicated, or abandoned.

1. A semiconductor device, comprising:
first and second emitter/collector regions, located respectively on first and second faces of a die of semiconductor material, and each doped to have a first conductivity type; wherein the die has a second conductivity type in the bulk thereof;
first and second base contact regions, located respectively on the first and second faces of the die, and each doped to have the second conductivity type;
first and second insulated gate electrodes which each lie in a trench, and are vertically extended alongside the first and second emitter/collector regions respectively;
first and second source regions, located at the edge of the respective emitter/collector regions alongside the trench, and separated from the bulk of the wafer by the emitter/collector region;
wherein the gate electrodes are capacitively coupled to selectably invert portions of the emitter/collector regions which are adjacent to a respective gate electrode;
whereby the gate electrodes can turn on conduction, even if no current is passed through either base contact region, by selectably inverting the adjacent portions of the respective emitter/collector region; and whereby the gate electrode also improves the breakdown voltage between the two emitter/collector regions.

2. The device of claim 1, wherein the first conductivity type is n-type.

3. The device of claim 1, wherein the gate electrodes are doped polysilicon.

4. The device of claim 1, wherein the gate electrodes turn on the adjacent portions of the respective emitter/collector region at a threshold voltage in the range of 2 to 10 Volts.

5. The device of claim 1, wherein the die is monocrystalline silicon.

6. The device of claim 1, wherein the walls of the trenches are lined with a thin layer of grown silicon dioxide.

7. A semiconductor device, comprising:
first and second emitter/collector regions, located respectively on first and second faces of a wafer of semiconductor material, and each doped to have a first conductivity type; wherein the wafer has a second conductivity type in the bulk thereof;
first and second base contact regions, located respectively on the first and second faces of the wafer, and each doped to have the second conductivity type;
first and second insulated gate electrodes which each lie in a trench, and are vertically extended alongside the first and second emitter/collector regions respectively; wherein the trench laterally surrounds the emitter/collector regions, and laterally separates the emitter/collector regions from the base contact regions;
first and second source regions, connected to and located in the respective emitter/collector regions at an edge alongside the trench, and separated from the bulk of the wafer by the emitter/collector region;
wherein the gate electrodes are capacitively coupled to selectably invert adjacent portions of the emitter/collector regions;
and wherein the trenches are deeper than the adjacent portions of the respective emitter/collector regions;
whereby one of the gate electrodes can turn on conduction, even if no current is passed through either base contact region, by inverting the adjacent portion of the respective emitter/collector region; and whereby the gate electrodes also improve the breakdown voltage between the two emitter/collector regions.

8. The device of claim 7, wherein the first conductivity type is n-type.

9. The device of claim 7, wherein the gate electrodes are doped polysilicon.

10. The device of claim 7, wherein the gate electrodes turn on the adjacent portions of the respective emitter/collector region at a threshold voltage in the range of 2 to 10 Volts.

11. The device of claim 7, wherein the die is monocrystalline silicon.

12. The device of claim 7, wherein the walls of the trenches are lined with a thin layer of grown silicon dioxide.

13. A semiconductor device, comprising:
first and second n-type emitter/collector regions, located respectively on first and second faces of a die of p-type semiconductor material;
first and second p-type base contact regions, located respectively on the first and second faces of the die;
first and second insulated gate electrodes which each lie in a trench, and are vertically extended alongside the first and second emitter/collector regions respectively; wherein the gate electrodes are made of polycrystalline p-type semiconductor material;
first and second p-type source regions, connected to and located in the respective emitter/collector regions at an edge alongside the trench, and separated from the bulk of the wafer by the emitter/collector region;
wherein the gate electrodes are capacitively coupled to selectably invert adjacent portions of the emitter/collector regions;
whereby one of the gate electrodes can turn on conduction, even if no current is passed through either base contact region, by inverting the adjacent portion of the respective emitter/collector region; and whereby the gate electrodes also improve the breakdown voltage between the two emitter/collector regions.

14. The device of claim 13, wherein the first conductivity type is n-type.

15. The device of claim 13, wherein the gate electrodes are doped polysilicon.

16. The device of claim 13, wherein the gate electrodes turn on the adjacent portions of the respective emitter/collector region at a threshold voltage in the range of 2 to 10 Volts.

17. The device of claim 13, wherein the die is monocrystalline silicon.

18. The device of claim 13, wherein the walls of the trenches are lined with a thin layer of grown silicon dioxide.

19-60. (canceled)
